(19) United States
(12) Patent Application Publication
(10) Pub. No.: US 2025/0128985 A1
(43) Pub. Date: Apr. 24, 2025

(54) GLASS ARTICLE, METHOD OF PRODUCING GLASS ARTICLE, AND DISPLAY DEVICE

(71) Applicant: Samsung Display Co., LTD., Yongin-si (KR)

(72) Inventors: Seung Ho KIM, Yongin-si (KR); Jin Won JANG, Yongin-si (KR); Nam Soo KANG, Yongin-si (KR); Byeong Beom KIM, Yongin-si (KR); Seung KIM, Yongin-si (KR); Jin Su NAM, Yongin-si (KR); Cheol Min PARK, Yongin-si (KR); Gyu In SHIM, Yongin-si (KR); Jae Gil LEE, Yongin-si (KR)

(21) Appl. No.: 18/677,848

(22) Filed: May 29, 2024

(30) Foreign Application Priority Data
Oct. 18, 2023 (KR) 10-2023-0139117

(51) Int. Cl. C03C 21/00; C03C 15/00; C03C 23/00; H05K 5/03

(52) U.S. Cl. CPC C03C 21/002; C03C 15/00; C03C 23/0075; H05K 5/03

(57) ABSTRACT

A glass article, a method of producing a glass article, and a display device are provided. The glass article, has a ratio of an intensity of hydrogen ions at a depth of 30 nm from a surface to an intensity of hydrogen ions at the surface that is equal to or greater than 1:4.

### CROSS-REFERENCE TO RELATED APPLICATION

The present application claims priority to and the benefit of Korean Patent Application No. 10-2023-0139117, filed on Oct. 18, 2023, in the Korean Intellectual Property Office, the entire content of which is hereby incorporated by reference.

### BACKGROUND

### 1. Field

Embodiments of the present disclosure relates to a glass article, a method of producing a glass article, and a display device.

### 2. Description of the Related Art

Glass articles are widely used in electronic devices including display devices and/or construction materials. For example, glass articles are employed as a substrate for a flat-panel display device such as a liquid-crystal display (LCD) device, an organic light-emitting display (OLED) device and an electrophoretic display (EPD) device, and/or a window for protecting them.

As portable electronic devices such as smart phones and tablet PCs prevail, a glass article employed thereby is frequently exposed to external impact. There is a demand for the development of glass articles that are thin for easy transport and can withstand external shocks.

Recently, a foldable display device has been studied for user convenience. A glass article applied to a foldable display device should have a small thickness in order to relieve bending stress when it is folded and to have strength capable of withstanding external shock. Accordingly, there have been attempts to improve the strength of a thin glass article by changing the production process conditions of the glass article.

### SUMMARY

Aspects of embodiments of the present disclosure provide a glass article that can improve impact resistance, a method of producing a glass article, and a display device.

It should be noted that objects of embodiments of the present disclosure are not limited to the above-mentioned object; and other objects of embodiments of the present disclosure will be apparent to those skilled in the art from the following descriptions.

According to an aspect of embodiments of the present disclosure, a glass article wherein a ratio of an intensity (e.g., concentration) of hydrogen ions at a depth of 30 nm from a surface to an intensity (e.g., concentration) of hydrogen ions at the surface is equal to or greater than 1:4.

In an embodiment, the ratio of the intensity (e.g., concentration) of hydrogen ions at the depth of 30 nm from the surface to the intensity (e.g., concentration) of hydrogen ions at the surface ranges from 1:4 to 1:6.

In an embodiment, a ratio of an intensity (e.g., concentration) of alkali ions at a depth of 30 nm from the surface to an intensity (e.g., concentration) of alkali ions at the surface ranges from 1:0.05 to 1:0.1.

In an embodiment, the glass article includes LAS glass-ceramic.

In an embodiment, the glass article includes SiO₂, Li₂O and Al₂O₃, and further includes at least one selected from Na₂O, K₂O, MgO, P₂O₅, B₂O₃, CaO, SrO, BaO, ZnO, TiO₂ and ZrO₂.

In an embodiment, the glass article has a thickness in a range from 20 μm to 100 μm.

In an embodiment, the glass article is foldable.

According to an aspect of embodiments of the present disclosure, a method of producing a glass article includes forming glass, stacking the glass to create a stack of glasses, cutting the stack of glasses to separate it into individual glasses, first healing the glass, first cleaning the glass, strengthening the glass, second cleaning the glass, second healing the glass, and third cleaning the glass, wherein at least one of the first cleaning, the second cleaning and the third cleaning uses deionized water at a temperature in a range of 80° C. to 100° C.

In an embodiment, at least one selected from the first cleaning, the second cleaning and the third cleaning is performed by dipping or spraying.

In an embodiment, at least one selected from the first cleaning, the second cleaning and the third cleaning is performed for several minutes to tens of minutes.

In an embodiment, hydrogen ions and alkali ions are ion-exchanged at a surface of the glass in at least one selected from the first cleaning, the second cleaning and the third cleaning.

In an embodiment, the method further includes fourth cleaning the glass between the separating and the first healing, wherein the fourth cleaning uses deionized water at a temperature in a range of 80° C. to 100° C.

In an embodiment, the method further includes chamfering the glass after the cutting the stack of glasses, wherein the chamfering is carried out via a chemical polishing process.

According to an aspect of embodiments of the present disclosure, a display device includes a display panel including a plurality of pixels, a cover window on the display panel, and an optically clear coupling layer between the display panel and the cover window, wherein a ratio of an intensity (e.g., concentration) of hydrogen ions at a depth of 30 nm from a surface of the cover window to an intensity (e.g., concentration) of hydrogen ions at the surface is equal to or greater than 1:4.

In an embodiment, the ratio of the intensity (e.g., concentration) of hydrogen ions at the depth of 30 nm from the surface to the intensity (e.g., concentration) of hydrogen ions at the surface ranges from 1:4 to 1:6 in the cover window.

In an embodiment, a ratio of an intensity (e.g., concentration) of alkali ions at a depth of 30 nm from the surface to an intensity (e.g., concentration) of alkali ions at the surface ranges from 1:0.05 to 1:0.1 in the cover window.

In an embodiment, the cover window includes LAS glass-ceramic.

In an embodiment, the cover window includes SiO₂, Li₂O and Al₂O₃, and further includes at least one selected from Na₂O, K₂O, MgO, P₂O₅, B₂O₃, CaO, SrO, BaO, ZnO, TiO₂ and ZrO₂.

In an embodiment, the cover window has a thickness in a range from 20 μm to 100 μm.

In an embodiment, the cover window is foldable.

According to an embodiment of the present disclosure, the intensity (e.g., concentration) of hydrogen ions can be increased while the intensity (e.g., concentration) of alkali ions can be reduced on the surface of the glass during a process of cleaning a glass article. Accordingly, the impact resistance of the glass article can be improved.

It should be noted that effects of embodiments of the present disclosure are not limited to those described above and other effects of embodiments of the present disclosure will be apparent to those skilled in the art from the following descriptions.

### BRIEF DESCRIPTION OF THE DRAWINGS

The above and other aspects and features of embodiments of the present disclosure will become more apparent by describing in more detail embodiments thereof with reference to the attached drawings, in which:

FIG. 1 is a perspective view of glass articles according to various embodiments.

FIG. 2 is a perspective view showing a display device employing a glass article according to an embodiment of the present disclosure when it is unfolded.

FIG. 3 is a perspective view showing the display device of FIG. 2 when it is folded.

FIG. 4 is a cross-sectional view showing an example where the glass article according to an embodiment of the present disclosure is employed as a cover window of a display device.

FIG. 5 is a cross-sectional view of a glass article having the shape of a flat plate according to an embodiment of the present disclosure.

FIG. 6 is a graph showing the stress profile of a glass article according to an embodiment of the present disclosure.

FIG. 7 is a flowchart illustrating a method of producing a glass article according to an embodiment of the present disclosure.

FIG. 8 is a view illustrating a cleaning process according to an embodiment.

FIG. 9 is a view illustrating ion exchange in the cleaning process according to an embodiment.

FIG. 10 is a view illustrating ion exchange in a strengthening process according to an embodiment.

FIG. 11 is a graph showing the results of a pen pressure test of glass according to Examples and a Comparative Example.

FIG. 12 is a graph showing the results of a pen drop test of glass according to Examples and a Comparative Example.

FIG. 13 is a graph showing the distribution of hydrogen ions in the glass article measured according to an Example and a Comparative Example.

FIG. 14 is a graph showing the distribution of alkali ions in the glass article measured according to an Example and a Comparative Example.

### DETAILED DESCRIPTION

The subject matter of the present disclosure will now be described more fully hereinafter with reference to the accompanying drawings, in which preferred embodiments of the disclosure are shown. The subject matter of this disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the spirit or scope of the present disclosure. Similarly, the second element could also be termed the first element.

Each of the features of the various embodiments of the present disclosure may be combined or combined with each other, in part or in whole, and technically various suitable interlocking and driving are possible. Each embodiment may be implemented independently of each other or may be implemented together in an association.

Hereinafter, embodiments of the present disclosure will be described with reference to the accompanying drawings.

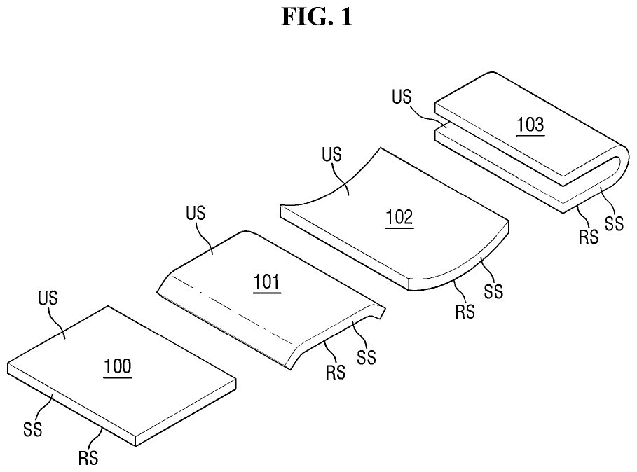

FIG. 1 is a perspective view of glass articles according to various embodiments.

The glass may be used as a cover window for protecting a display, a substrate for a display panel, a substrate for a touch panel, an optical member such as a light guide plate, etc. in electronic devices including a display, such as a tablet PC, a notebook PC, a smart phone, an electronic book, a television and/or a PC monitor as well as a refrigerator and/or a washing machine including a display screen. Glass may also be employed as a cover glass for an instrument panel in a vehicle, a cover glass for solar cells, interior materials for construction materials, windows for buildings and/or houses, etc.

Glass should have high strength. For example, when glass is employed as a window, it is desirable to have a small thickness and a high strength such that it is not easily broken by an external impact, because it should have a high transmittance and a small weight. Glass having a high strength can be produced by, for example, chemical strengthening and/or thermal tempering. Examples of a variety of shapes of tempered glasses are shown in FIG. 1.

Referring to FIG. 1, in an embodiment, the glass article 100 may have the shape of a flat sheet or a flat plate. In another embodiment, the glass articles 101, 102 and 103 may each have a three-dimensional shape including bent portions. For example, the edge of the flat portion may be curved (e.g., the glass article 101), the entire surface may be curved (e.g., the glass article 102) and/or folded (the glass article 103). In some embodiments, the glass article 100 may be a foldable glass article that has a flat sheet or flat plate shape and is flexible so that it can be folded and/or bent. In some embodiments, the glass article 100 may be stretched and/or rolled. The glass articles 100, 101, 102 and 103 may each have a first surface US, a second surface RS, and side surfaces SS.

The shape of the glass articles 100 to 103 may be, but is not limited to being, a rectangle when viewed from the top. For example, the glass articles 100 to 103 may have various suitable shapes such as a rounded rectangle, a square, a circle, and/or an ellipse. In the following description, a glass article having the shape of a rectangular flat plate will be described as an example of the glass articles 100 to 104. It is, however, to be understood that the present disclosure is not limited thereto.

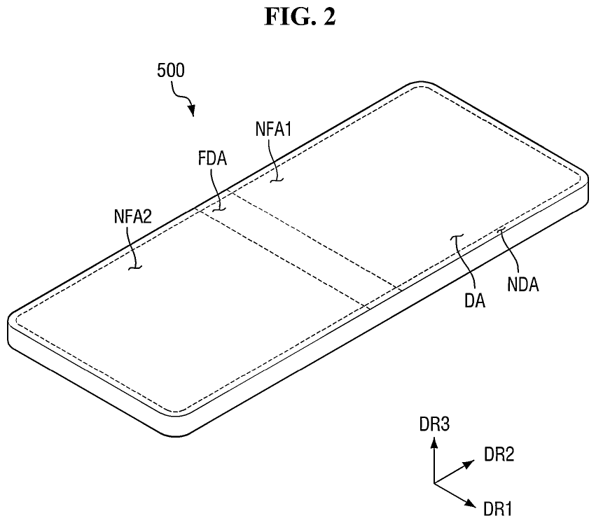

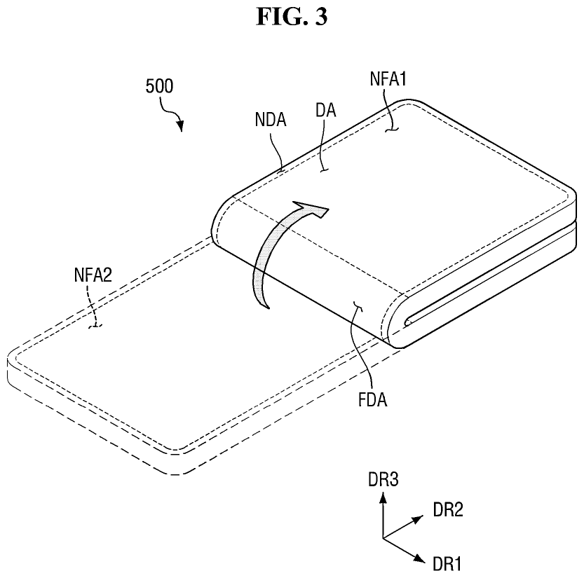

FIG. 2 is a perspective view showing a display device employing a glass article according to an embodiment of the present disclosure when it is unfolded. FIG. 3 is a perspective view showing the display device of FIG. 2 when it is folded.

Referring to FIGS. 2 and 3, a display device 500 according to an embodiment may be a foldable display device. As will be further described below, the display device 500 may employ the glass article 100 of FIG. 1 as a cover window, and the glass article 100 may be flexible and foldable.

As shown in FIGS. 2 and 3, a first direction DR1 may refer to a direction parallel to a side of the display device 500, for example, the horizontal direction of the display device 500 when viewed from the top. A second direction DR2 may refer to a direction parallel to another side of the display device 500 that meet the side of the display device 500, for example, the vertical direction of the display device 10 when viewed from the top. A third direction DR3 may refer to a thickness direction of the display device 500.

According to an embodiment of the present disclosure, the display device 500 may have a rectangular shape when viewed from the top. The display device 500 may have a rectangular shape having sharp corners or a rectangular shape having rounded corners when viewed from the top. The display device 500 may include two shorter sides extended in the first direction DR1 and two longer sides extended in the second direction DR2 when viewed from the top.

The display device 500 includes a display area DA and a non-display area NDA. The shape of the display area DA may conform to the shape of the display device 500 when viewed from the top. For example, when the display device 500 is rectangular when viewed from the top, the display area DA may also be rectangular.

The display area DA may include a plurality of pixels to display images. The plurality of pixels may be provided in a matrix pattern. The plurality of pixels may be, but is not limited to, a rectangle, a diamond, or a square when viewed from the top. For example, the plurality of pixels may be a quadrangle other than a rectangle, a diamond or a rectangle, a polygon other than a quadrangle, a circle, or an ellipse when viewed from the top.

The non-display area NDA may not include pixels and thus may not display images. The non-display area NDA may be provided around the display area DA. The non-display area NDA may surround the display area DA, but the present disclosure is not limited thereto. The display area DA may be partially surrounded by the non-display area NDA.

According to an embodiment, the display device 500 may remain folded as well as unfolded. The display device 500 may be folded inward (in-folding manner) so that the display device DA is located inside, as shown in FIG. 3. When the display device 500 is folded inward (in-folding), a portion of the upper surface of the display device 500 may face another part thereof. As another example, the display device 500 may be folded outward (out-folding) so that the display area DA is located outside. When the display device 500 is folded outward (out-folding), a portion of the lower surface of the display device 500 may face another part thereof.

According to an embodiment of the present disclosure, the display device 500 may be a foldable device. As used herein, a foldable device refers to a display device that can be folded and can be switched between a folded state and an unfolded state. When a device is folded, the device is typically folded at an angle of approximately 180°. It is, however, to be understood that the present disclosure is not limited thereto. For example, when a device is folded at an angle greater than or less than 180°, e.g., at an angle of 90° or more but less than 180° or an angle of 120° or more and less than 180°, the device is also referred to as being folded. In some embodiments, even when a device is not completely folded, the device may be referred to as being folded if the device is not unfolded but is somewhat bent. For example, even if a device is bent at an angle of 90 degrees or less, the device may be referred to as being folded in order to distinguish it from being unfolded as long as the maximum folding angle is 90 degrees or more. When the display device is folded, the radius of curvature may be 5 mm or less, for example, in the range of 1 mm to 2 mm, or may be approximately 1.5 mm. It should be understood that the present disclosure is not limited thereto.

According to an embodiment of the present disclosure, the display device 500 may include a folding area FDA, a first non-folding area NFA1, and a second non-folding area NFA2. The display device 500 can be folded at the folding area FDA, while it cannot be folded at the first non-folding area NFA1 and the second non-folding area NFA2.

The first non-folding area NFA1 may be on one side, for example, the upper side of the folding area FDA. The second non-folding area NFA2 may be on the other side, for example, the lower side of the folding area FDA. The folding area FDA may be a curved area having a set predetermined curvature.

According to an embodiment, the folding area FDA may be located at a set or particular position in the display device 500. In the display device 500, one or more folding areas FDA may be located at the set or particular position(s). According to another embodiment, the position of the folding area FDA may not be constrained in the display device 500 but may be freely formed in different areas.

According to an embodiment, the display device 500 may be folded in the second direction DR2. Accordingly, the length of the display device 10 in the second direction DR2 may be reduced to about half, so that the display device 500 is easy to carry.

According to an embodiment of the present disclosure, the folding direction of the display device 500 is not limited to the second direction DR2. For example, the display device 500 may be folded in the first direction DR1. In some embodiments, the length of the display device 10 in the first direction DR1 may be reduced to about half.

In the drawings, each of the display area DA and the non-display area NDA overlaps the folding area FDA, the first non-folding area NFA1 and the second non-folding area NFA2. It is, however, to be understood that the present disclosure is not limited thereto. For example, each of the display area DA and the non-display area NDA may overlap at least one of the folding area FDA, the first non-folding area NFA1, and the second non-folding area NFA2.

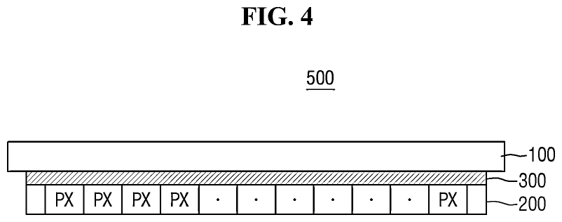

FIG. 4 is a cross-sectional view showing an example where the glass article according to an embodiment of the present disclosure is employed as a cover window of a display device.

Referring to FIG. 4, the display device 500 may include a display panel 200, a glass article 100 on the display panel 200 and working as a cover window, and an optically transparent coupling layer between the display panel 200 and the glass article 100 to couple them.

The display panel 200 may include, for example, a self-luminous display panel such as an organic light-emitting display panel (OLED), an inorganic light-emitting display panel (inorganic EL), a quantum-dot light-emitting display panel (QED), a micro LED display panel (micro-LED), a nano LED display panel (nano-LED), a plasma display panel (PDP), a field emission display panel (FED) and/or a cathode ray display panel (CRT), as well as a light-receiving display panel such as a liquid-crystal display panel (LCD) and/or an electrophoretic display panel (EPD).

The display panel 200 may include a plurality of pixels PX and may display images by using light emitted from each of pixels PX. The display device 500 may further include a touch member. According to an embodiment of the present disclosure, the touch member may be incorporated into the display panel 200. For example, the touch member may be formed directly on a display member of the display panel 200 and thus the display panel 200 itself may perform or provide a touch feature. According to another embodiment, the touch member may be fabricated separately from the display panel 200 and then attached to the upper surface of the display panel 200 by an optically transparent coupling layer.

The glass article 100 protecting the display panel 200 is above the display panel 200. The glass article 100 may be larger than the display panel 200 so that side surfaces thereof may protrude outwardly from the side surfaces of the display panel 200. It is, however, to be understood that the present disclosure is not limited thereto. The display device 500 may further include a printed layer on at least one surface of the glass article 100 at the edge of the glass article 100. The printed layer of the display device 500 may hide the bezel of the display device 500 from the outside and may give a decoration in some embodiments.

The optically transparent coupling layer 300 is between the display panel 200 and the glass article 100. The optically transparent coupling layer 300 serves to fix the glass article 100 on the display panel 200. The optically transparent coupling layer 300 may include an optically clear adhesive (OCA), an optically clear resin (OCR), etc.

Hereinafter, the above-described tempered glass article 100 will be described in more detail.

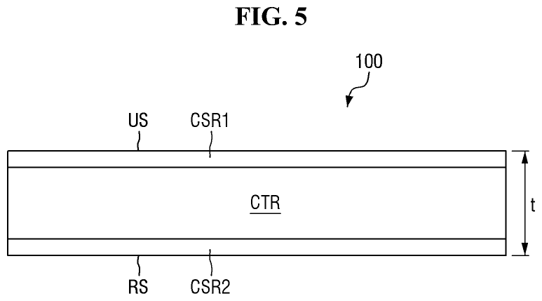

FIG. 5 is a cross-sectional view of a glass article having the shape of a flat plate according to an embodiment of the present disclosure.

Referring to FIG. 5, the glass article 100 may include a first surface US, a second surface RS, and side surfaces. In the glass article 100 having the shape of a flat plate, the first surface US and the second surface RS are main surfaces having a large area, and side surfaces SS (shown in FIG. 1) are outer surfaces connecting the first surface US with the second surface RS.

The first surface US and the second surface RS are opposed to each other (e.g., face away from each other) in the thickness direction. When the glass article 100 serves to transmit light like a cover window of a display, the light may be mainly incident on the first surface US or the second surface RS to exit through the other.

A thickness t of the glass article 100 is defined as the distance between the first surface US and the second surface RS. The thickness t of the glass article 100 may be, but is not limited to, 100 μm or less, or, for example, may range from 20 μm to 100 μm. According to an embodiment of the present disclosure, the thickness t of the glass article 100 may be 80 μm or less. According to another embodiment, the thickness t of the glass article 100 may be approximately 75 μm or less. According to yet another embodiment, the thickness t of the glass article 100 may be approximately 70 μm or less. According to yet another embodiment, the thickness t of the glass article 100 may be approximately 60 μm or less. According to yet another embodiment, the thickness t of the glass article 100 may be approximately 65 μm or less. According to yet another embodiment, the thickness t of the glass article 100 may be approximately 50 μm or less. According to yet another embodiment, the thickness t of the glass article 100 may be approximately 30 μm or less. In some embodiments, the thickness t of the glass article 100 may be in the range of 20 μm to 50 μm, or approximately 30 μm. The glass article 100 may have a uniform thickness t or may have different thicknesses for different regions (e.g., may have a non-uniform thickness t).

The glass article 100 may be tempered to have a set or predetermined stress profile therein. The tempered glass article 100 can better prevent or reduce occurrence and/or propagation of cracks, breakage due to external impact, etc., compared to the glass article 100 before it is tempered. The glass article 100 tempered via a tempering process may have different stresses depending on its different regions. For example, compressive regions CSR1 and CSR2 where compressive stress acts may be in the vicinity of the surfaces of the glass article 100, e.g., near the first surface US and the second surface RS, and a tensile region CTR where tensile stress acts may be inside the glass article 100. The boundary between the tension region CTR and each of the compressive regions CSR1 and CSR2 may have a stress value of zero. The value of the compressive stress in each of the compressive regions CSR1 and CSR2 may vary depending on the position (e.g., depth from the surface). In some embodiments, the tensile region CTR may also have different stress values depending on the depth from the surfaces US and RS.

The position of the compressive regions CSR1 and CSR2 in the glass article 100, the stress profile in the compressive regions CSR1 and CSR2, the compressive energy of the compressive regions CSR1 and CSR2, the tensile energy of the tensile region CTR, etc. may greatly affect the mechanical properties of the glass article 100, such as surface strength.

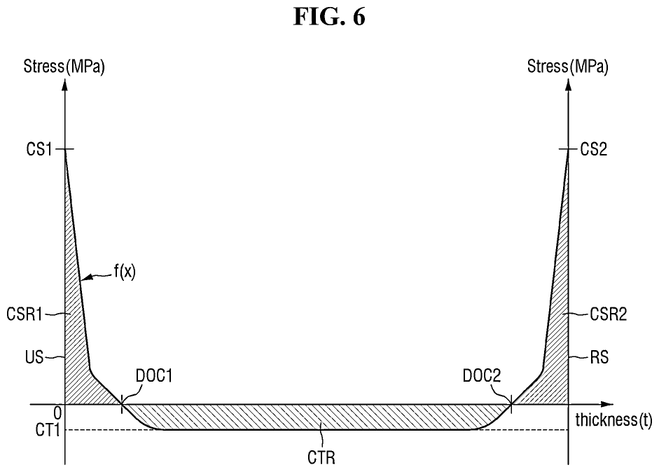

FIG. 6 is a graph showing the stress profile of a glass article according to an embodiment of the present disclosure. In the graph of FIG. 6, the x-axis represents the thickness direction of the glass article. In FIG. 6, the compressive stress has positive values, while the tensile stress has negative values. Herein, the magnitudes of the compressive/tensile stresses mean the absolute values regardless of their signs.

Referring to FIG. 6, the glass article 100 includes a first compressive region CSR1 that is extended (or expanded) from the first surface US to a first compression depth DOC1, and a second compressive region CSR2 that is extended (or expanded) from the second surface RS to a second compression depth DOC2. A tensile region CTR is between the first compression depth DOC1 and the second compression depth DOC2. The stress profile on the surface US and the stress profile on the surface RS of the glass article 100 may be symmetrical with respect to the center of the thickness (t) direction. In some embodiments, compressive regions and a tensile region may be formed between the opposed side surfaces of the glass article 100 in a similar manner.

The first compressive region CSR1 and the second compressive region CSR2 are resistant to an external impact to prevent or reduce occurrence of cracks in the glass article 100 and/or damage to the glass article 100. The larger maximum compression stresses CS1 and CS2 of the first compressive region CSR1 and the second compressive region CSR2 are, the higher the strength of the glass article 100 is. Because an external impact is usually transmitted through the surfaces of the glass article 100, it is beneficial or advantageous to have the maximum compressive stresses CS1 and CS2 at the surfaces of the glass article 100 in terms of durability. in view of the above, the compressive stresses of the first compressive region CSR1 and the second compressive region CSR2 are the largest at the surfaces and generally decrease toward the inside.

The first compression depth DOC1 and the second compression depth DOC2 suppress or reduce propagation of cracks and/or grooves formed in the first surface US and the second surface RS to the tensile region CTR inside the glass article 100. The larger the first compression depth DOC1 and the second compression depth DOC2 are, the better the propagation of cracks and/or the like can be prevented or reduced. The positions of the first compression depth DOC1 and the second compression depth DOC2 are the boundaries between the tension region CTR and each of the compressive regions CSR1 and CSR2, where the stress value is zero.

Throughout the glass article 100, the tensile stress of the tensile region CTR may be balanced with the compressive stresses of the compressive regions CSR1 and CSR2. In some embodiments, in the glass article 100, the sum of the compressive stresses (e.g., the compressive energies) may be equal to the sum of tensile stresses (e.g., the tensile energies). The stress energies accumulated in an area having a constant width in the thickness t direction in the glass article 100 may be calculated by integrating the stress profile. When the stress profile in the glass article 100 having the thickness of t is represented by the function f(x), the following relationship can be established:

$${\int }_{0}^{t} f ( x ) dx = 0 \qquad Equation 1$$

The larger the tensile stress inside the glass article 100 is, the more likely the fragments to be vigorously released when the glass article 100 is broken, and the more likely the glass article 100 is to be crushed from the inside. For example, the maximum tensile stress that meets the frangibility requirements of the glass article 100 may satisfy the following relationship:

$${CT}_{1} \leq - 38.7 \times ln ( t ) + 48.2 \qquad Equation 2$$

In some embodiments, the maximum tensile stress CT1 may be 100 MPa or less, or 85 MPa or less. In order to improve mechanical properties such as strength, it may be desirable that the maximum tensile stress CT1 is 75 MPa or more. According to an embodiment of the present disclosure, the maximum tensile stress CT1 may be, but is not limited to being, above 75 MPa and below 85 Mpa.

The maximum tensile stress CT1 of the glass article 100 may be generally located at a center portion of the glass article 100 in the thickness t direction. For example, the maximum tensile stress CT1 of the glass article 100 may be located at a depth in the range of 0.4t to 0.6t, or in the range of 0.45t to 0.55t, or at a depth of approximately 0.5t.

Although it is desired that the compressive stresses and the compression depths DOC1 and DOC2 have large values in order to increase the strength of the glass article 100, the tensile stress may also be increased as the tensile energy is increased with the compressive energy. In order to meet the frangibility requirements while having a high strength, it may be desirable to adjust the stress profile so that the maximum compressive stresses CS1 and CS2 and the compression depths DOC1 and DOC2 have large values while the compressive energy is reduced. To this end, the glass article 100 may be produced by a glass composition containing certain components in set or predetermined contents (e.g., amounts). Depending on the composition ratio of the components contained in the glass composition, the glass article 100 can have excellent strength, as well as flexibility and properties so that it can be applied to a foldable display device.

Hereinafter, a method of producing a glass article will be described. In the following description, the same or similar elements will be denoted by the same or similar reference numerals, and redundant descriptions will be omitted or briefly described.

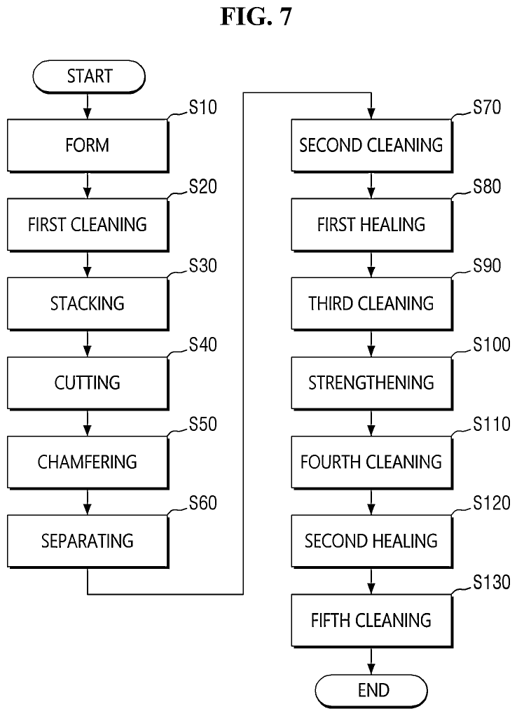

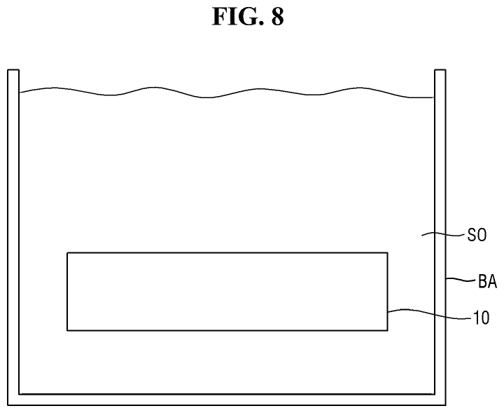

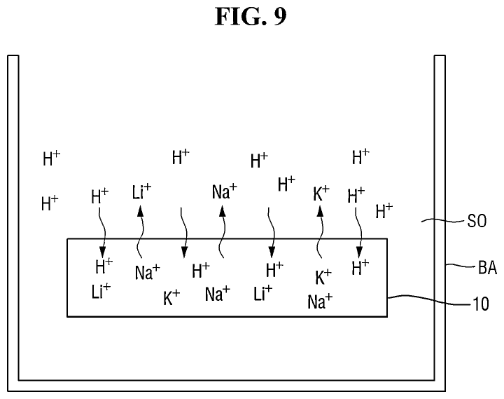

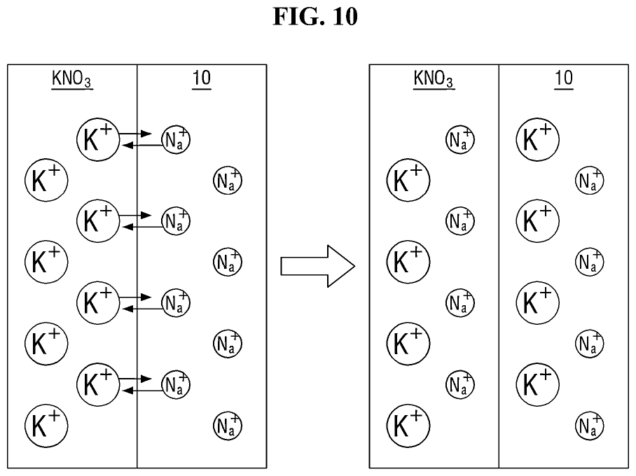

FIG. 7 is a flowchart illustrating a method of producing a glass article according to an embodiment of the present disclosure. FIG. 8 is a view illustrating a cleaning process according to an embodiment. FIG. 9 is a view illustrating ion exchange in the cleaning process according to the embodiment. FIG. 10 is a view illustrating ion exchange in a strengthening process according to an embodiment.

Referring to FIGS. 7 to 10, a method of producing a glass article according to an embodiment may include forming (S10), first cleaning (S20), stacking (S30), cutting (S40), chamfering (S50), separating (S60), second cleaning (S70), first healing (S80), third cleaning (S90), strengthening (S100), fourth cleaning (S110), second healing (S120), and fifth cleaning (S130).

The forming S10 may include preparing a glass composition, and forming the glass composition.

The glass compositions may include a variety of suitable compositions generally used in the art. According to an embodiment of the present disclosure, the glass composition may include LAS glass ceramics containing lithium aluminosilicates. For example, the glass composition may contain 50 to 80 mol % of SiO₂, 1 to 30 mol % of Al₂O₃, 0 to 5 mol % of B₂O₃, 0 to 4 mol % of P₂O₅, 3 to 20 mol % Li₂O, 0 to 20 mol % Na₂O, 0 to 10 mol % of K₂O, 3 to 20 mol % of MgO, 0 to 20 mol % of CaO, 0 to 20 mol % of SrO, 0 to 15 mol % of BaO, 0 to 10 mol % of ZnO, 0 to 1 mol % of TiO₂, and/or 0 to 8 mol % of ZrO₂. It should be understood, however, that the present disclosure is not limited thereto. The glass composition may include SiO₂, Al₂O₃ and Li₂O, and may further include one or more selected from B₂O₃, P₂O₅, Na₂O, K₂O, MgO, CaO, SrO, BaO, ZnO, TiO₂, and ZrO₂.

As used herein, the content of 0 mol % of a component refers to that the component is substantially not contained. As used herein, a phrase “a composition substantially does not include a particular component” refers to that the component is intended not to be contained in a raw material and/or the like, and a small amount of impurities of 0.1 mol % or less may be inevitably contained.

The components of the glass composition will be described in more detail. The glass includes or consists mainly of SiO₂, which can increase chemical durability and can suppress or reduce occurrence of cracks when scratches (indentations) are formed on a surface of the glass. In order to sufficiently achieve the above effects, SiO₂ content may be 50 mol % or more. In order to exhibit sufficient fusibility, SiO₂ content may be 80 mol % or less in the glass composition.

Al₂O₃ provides the glass with better characteristics when it is broken. In other words, when the glass is broken, Al₂O₃ may reduce the number of fragments that are formed. In some embodiments, Al₂O₃ may act as an effective component that improves ion exchange during chemical strengthening and increases surface compressive stress after the strengthening. When the content of Al₂O₃ is 1 mol % or more, the above effects can be effectively achieved. In some embodiments, in order to maintain the acid resistance and fusibility of the glass, it may be desirable to have the content of Al₂O₃ be 30 mol % or less.

B₂O₃ improves the chipping resistance of glass and improves fusibility. Although B₂O₃ may be eliminated or omitted (0 mol %), the fusibility of glass can be further improved when B₂O₃ is contained at 0.5 mol % or more. When the B₂O₃ content is 5 mol % or less, cord can be advantageously suppressed or reduced during melting.

P₂O₅ improves ion exchange performance and chipping resistance. Although P₂O₅ may be eliminated or omitted (0 mol %), the above functions can be significantly carried out when P₂O₅ is contained at 0.5 mol % or more. When the P₂O₅ content is equal to or less than 4 mol %, it may be advantageous or beneficial to prevent or reduce friability and acid resistance from significantly decreasing.

Li₂O forms surface compressive stress by ion exchange. Li ions near the glass surface may be exchanged for Na ions, etc. via an ion exchange process. Li₂O can also further improve the friability of glass. The content of Li₂O for effective ion exchange may be equal to or greater than 3 mol %. In terms of acid resistance, the content of Li₂O may be 20 mol % or less.

Na₂O forms surface compressive stress by ion exchange and improves the fusibility of the glass. Na ions near the glass surface may be exchanged for K ions, etc. via an ion exchange process. While Na₂O may be eliminated or omitted, in order to effectively achieve the above functions, it may be desirable to have the content of Na₂O be equal to or greater than 1 mol %. If there is only a Li ion and Na ion exchange process and no K ion exchange process, it may be desirable to have the Na₂O content be equal to or less than 8 mol % in order to facilitate Li ion and Na ion exchange. If a K ion exchange process is carried out together, a larger amount of Na₂O may be used. Even in this instance, however, it may be desirable to have the content of K ions be equal to or less than 20 mol % terms of acid resistance.

K₂O improves ion exchange performance and is related to friability. Although K₂O may be eliminated or omitted, it may be contained at 0.5 mol % or more to improve ion exchange performance. In order to avoid having friability that is too low, the content of K₂O may be equal to or less than 10 mol %.

MgO increases the surface compressive stress of chemically strengthened glass and improves its friability. The above functions can be effectively performed when the content of MgO is equal to or greater than 3 mol %. In order to suppress or reduce devitrification which may occur when glass is fused, it may be advantageous or beneficial to have the content of MgO be equal to or less than 20 mol %.

CaO improves the fusibility and friability of glass. CaO may be eliminated or omitted, and in order to effectively perform the above functions, it may be desirable to have the content of CaO be equal to greater than 0.5 mol %. If the CaO content is too large, the ion exchange performance may deteriorate. Accordingly, it may be desirable to have the CaO content be equal to or less than 20 mol %.

SrO improves the fusibility and friability of glass, like CaO. SrO may be eliminated or omitted, and in order to effectively perform the above functions, it may be desirable to have the content of SrO be equal to greater than 0.5 mol %. If the SrO content is too large, the ion exchange performance may deteriorate. Accordingly, it may be desirable to have the SrO content be equal to or less than 20 mol %.

BaO improves the fusibility and friability of glass. BaO may be eliminated or omitted, and in order to effectively perform the above functions, it may be desirable to have the content of BaO be equal to greater than 0.5 mol %. In order to avoid too low ion exchange performance, it may be advantageous or beneficial to have the BaO content be equal to or less than 15 mol %.

ZnO improves the fusibility of glass. ZnO may be eliminated or omitted, and the fusibility can be improved significantly when the content of ZnO is equal to or greater than 0.25 mol %. In order to prevent or reduce deterioration of weather resistance, it may be desirable to have the ZnO content be equal to or less than 10 mol %.

TiO₂ improves the friability of chemically strengthened glass. TiO₂ may be eliminated or omitted, and the friability can be improved significantly when the content is equal to or greater than 0.1 mol %. In order to prevent or reduce devitrification during fusing, it may be desirable to have the TiO₂ content be equal to or less than 1 mol %.

ZrO₂ may increase surface compressive stress by ion exchange and improve the friability of glass. ZrO₂ may be eliminated or omitted, and the above functions can be effectively performed when the content of ZrO₂ is equal to or greater than 0.5 mol %. In order to suppress or reduce devitrification during fusing, it may be advantageous or beneficial to have the ZrO₂ content be equal to or less than 8 mol %.

The glass composition may further include components such as Y₂O₃, La₂O₃, Nb₂O₅, Ta₂O₅ and/or Gd₂O₃ as desired, in addition to the components listed above. The composition of the glass article 100 may be changed via a molding process, an ion exchange process, etc., which will be further described below. In addition, the components and contents of the glass composition described above are merely examples, and the glass may be formed or modified by applying the contents of a variety of suitable components generally used in the art.

The glass composition described above may be molded into a plate glass shape by various suitable methods generally used in the art. For example, it may be molded by a float process, a fusion draw process, a slot draw process, etc.

Subsequently, the glass molded into a flat plate shape may be cleaned via the first cleaning S20. The first cleaning S20 may be a cleaning process that removes remaining particles from the previous process or processes. The cleaning process may be one of typically used processes. As an implementation, the cleaning process may be performed by spraying a washing liquid to clean the glass, and/or by dipping the glass in a washing liquid. The washing liquid is not particularly limited herein as long as it can clean glass surface. According to one or more embodiments, deionized water (DI water), or alkaline washing liquid containing potassium hydroxide (KOH) or sodium hydroxide (NaOH) may be used as the washing liquid. The cleaning process can be carried out in lukewarm water at room temperature or below 40° C.

Subsequently, the stacking S30 may be carried out to stack a number of glasses after the first cleaning S20. The stacking S30 is carried out to easily perform the subsequent cutting S40 by creating a stack of glasses because the glass is easily broken if it is cut one by one. The stacking S30 may include a process of bonding glasses.

In some embodiments, an adhesive may be applied to one or both surfaces of the glass in order to prevent or reduce occurrence of surface during the processes and to form a stack of glasses. For example, a stack of glasses may be created by applying an adhesive to one surface of a glass, stacking another glass on the glass to which the adhesive has been applied, applying an adhesive again on the glass, stacking yet another glass on it, and so on.

The method of applying the adhesive is not particularly limited herein. For example, it may be applied using a rubber roller having a set or certain softness on the surface. The adhesive is not particularly limited herein. For example, a UV adhesive or a natural adhesive such as rosin may be used as the adhesive.

Subsequently, the stack of glasses may be cut by the cutting S40. In the cutting S40, the final glass article may be shaped to fit the size of a device employing it. The stack of glasses may be processed as a large-area substrate as a unit of mother substrate, and the mother substrate may be cut into a plurality of cells. For example, if the final glass article has a size of approximately 6 inches, a stack of glasses having a size of several to hundreds of times the size of the glass article, e.g., 120 inches may be formed. Then, by cutting it, twenty stacks of glasses in a plate shape may be obtained at once. In this manner, the process efficiency can be improved over forming individual glass articles separately.

The cutting S40 is not particularly limited herein as long as the stack of glasses can be cut into cells. For example, the cutting S40 may be carried out using a diamond cutting wheel, laser, a cutting knife, etc.

Subsequently, the chamfering S50 may be carried out on the stack of glasses after cutting. The chamfering S50 may process the edges of each glass of the stack. For example, the cutting S40 may be a step of forming the cross-sectional shape of the stack of glasses cut into generally a C shape.

The chamfering S50 may be carried out by a chemical polishing process. The chemical polishing process may be carried out, for example, by dipping and/or spraying. A polishing liquid may include one or more selected from the group consisting of: hydrofluoric acid (HF), ammonium fluoride (NH₄F), ammonium hydrogen fluoride (NH₄HF₂), sodium fluoride (NaF), sodium hydrogen fluoride (NaHF₂), lithium fluoride (LiF), potassium fluoride (KF) and calcium fluoride CaF₂.

In some embodiments, physical polishing may be additionally carried out to remove chipping of the cross section of the stack of glasses prior to the chamfering S50. The stack of glasses subjected to the chamfering S50 can prevent or reduce occurrence of chipping due to cracked and/or dented edges.

Subsequently, the separating S60 the stack of glasses may be carried out. The separating S60 may include removing the adhesive applied to the stack of glasses to individually separate the glasses from the stack. The separating S60 may be performed by immersing the stack of glasses in a stripping solution containing a swelling agent for the adhesive and a surfactant.

Subsequently, the separated glasses may be cleaned by the second cleaning S70. According to an embodiment of the present disclosure, the second cleaning S70 may be carried out differently from the first cleaning S20 described above.

In some embodiments, the second cleaning S70 may be a cleaning process that removes residual particles and etchant from the previous processes and also improves the impact resistance of the glass. The second cleaning S70 may use deionized water (DI water). The deionized water may be used by spraying and/or dipping.

The second cleaning S70 may be carried out at a temperature of 80° C. to 100° C. By performing the second cleaning S70 in the above temperature range, hydrogen ions in the deionized water may diffuse into the glass and alkali ions in the glass may diffuse into the deionized water, such that they may be substituted with each other. The second cleaning S70 may be performed for several minutes to tens of minutes.

According to an embodiment, as shown in FIGS. 8 and 9, the second cleaning S70 may be performed by dipping a glass 10 in a bath BA containing deionized water SO. In doing so, the temperature may range from 80° C. to 100° C. In the glass 10 immersed in the deionized water SO, hydrogen ions (H+) of the deionized water SO move into the glass by mutual diffusion at a depth of several tens of nanometers (nm) from the surface, and alkali ions inside the glass 10, such as lithium ions (Li+), sodium ions (Na+) and potassium ions (K+), move to the deionized water SO, such that they are substituted with each other. In some embodiments, the higher the temperature of the deionized water SO is, the more likely the hydrogen ions are to penetrate the glass. In some embodiments, at a temperature of 95° C. or higher, hydrogen ions can better penetrate into the glass 10 to improve impact resistance.

Subsequently, the first healing S80 may be carried out on the glass. The first healing S80 can remove flaws in the glass and can improve the reduced strength of the side surfaces of the cut glass. The first healing S80 may be carried out via a chemical polishing process. The chemical polishing process may be carried out, for example, by dipping and/or spraying. A polishing liquid may include one or more selected from the group consisting of: hydrofluoric acid (HF), ammonium fluoride (NH₄F), ammonium hydrogen fluoride (NH₄HF₂), sodium fluoride (NaF), sodium hydrogen fluoride (NaHF₂), lithium fluoride (LiF), potassium fluoride (KF) and calcium fluoride CaF₂.

In some embodiments, polishing of the cut glass may be further performed after the first healing S80.

Subsequently, the third cleaning S90 may be performed on the glass. The third cleaning S90 may be a cleaning process that removes remaining particles and polishing liquid from the glass in the first healing S80 and also improves the impact resistance of the glass. The third cleaning S90 may be carried out in the same process as the second cleaning S70. For example, the third cleaning S90 may be carried out using deionized water (DI water) at a temperature of 80° C. to 100° C. In the third cleaning S90, hydrogen ions in deionized water diffuse into the glass, and alkali ions in the glass diffuse into deionized water, such that they are substituted with each other, thereby improving the impact resistance of the glass.

Subsequently, the strengthening S100 may be performed on the glass. The strengthening S100 may be carried out by chemical strengthening and/or thermal tempering. For ultra-thin glass, chemical strengthening may be suitable in order to precisely control the stress profile. In the following embodiments, chemical strengthening is applied as the glass strengthening S100.

Chemical strengthening may be carried out via an ion exchange process. The ion exchange process refers to a process of exchanging ions inside glass with other ions. The ion exchange process allows ions on or near the surface of the glass to be replaced or exchanged by larger ions having the same valence or oxidation state. For example, when glass contains a monovalent alkali metal such as Li+, Na+, K+ and Rb+, the monovalent cations on the surface may be exchanged with Na+, K+, Rb+, or Cs+ ions each having a larger ionic radius. The ion exchange process will be described in more detail with reference to FIG. 10.

Referring to FIG. 10, when the glass 10 containing sodium ions is exposed to potassium ions by immersing the glass in a molten salt bath containing potassium nitrate (KNO₃), sodium ions in the glass are discharged to the outside and the potassium ions can replace them. The exchanged potassium ions generate compressive stress because they have a larger ionic radius than sodium ions. The more potassium ions are exchanged, the greater the compressive stress becomes. Because the ion exchange takes place through the surface of the glass, the amount of potassium ions on the glass surface may be the greatest. Some of the exchanged potassium ions may diffuse into the glass to increase the depth of the compressive region, e.g., the depth of the compression, but the amount may reduce away from the surface. Thus, the glass may have a stress profile that has the greatest compressive stress on the surface and decreases toward the inside of the glass. However, embodiments are not limited to the above examples. The stress profile may be altered depending on the temperature, time and the number of the ion exchange process, whether heat treatment is carried out, etc.

The ion exchange process may be carried out two or more times. For example, the ion exchange process may include a primary ion exchange process and a secondary ion exchange process. The primary and secondary ion exchange processes may be carried out in different water baths. The ion exchange processes may be carried out concurrently (e.g., simultaneously) on a number of glasses. In some embodiments, a number of glasses may be immersed in a single bath, and ion exchange may be carried out concurrently (e.g., simultaneously) in the glasses 10.

Subsequently, the fourth cleaning S110 may be carried out. The fourth cleaning S110 may be a cleaning process that removes remaining particles and molten salts from the glass in the strengthening S100 and also improves the impact resistance of the glass. The fourth cleaning S110 may be the same process as the second cleaning S70 and the third cleaning S90 described above. For example, the fourth cleaning S110 may be carried out using deionized water (DI water) at a temperature of 80° C. to 100° C. In the fourth cleaning S110, hydrogen ions in deionized water diffuse into the glass, and alkali ions in the glass diffuse into deionized water, such that they are substituted with each other, thereby improving the impact resistance of the glass.

Subsequently, the second healing S120 may be carried out. Flaws in the glass can be removed in the second healing S120. The second healing S120 may be carried out via a chemical polishing process. The chemical polishing process may be carried out, for example, by dipping and/or spraying. A polishing liquid may include one or more selected from the group consisting of: hydrofluoric acid (HF), ammonium fluoride (NH₄F), ammonium hydrogen fluoride (NH₄HF₂), sodium fluoride (NaF), sodium hydrogen fluoride (NaHF₂), lithium fluoride (LiF), potassium fluoride (KF) and calcium fluoride CaF₂.

Lastly, the fifth cleaning S130 may be carried out. The fifth cleaning S130 may be a cleaning process that removes remaining particles and etchant from the glass in the second healing S120 and also improves the impact resistance of the glass. The fifth cleaning S130 may be the same process as the second cleaning S70, the third cleaning S90 and the fourth cleaning S110 described above. For example, the fifth cleaning S130 may be carried out using deionized water (DI water) at a temperature of 80° C. to 100° C. In the fifth cleaning S130, hydrogen ions in deionized water diffuse into the glass, and alkali ions in the glass diffuse into deionized water, such that they are substituted with each other, thereby improving the impact resistance of the glass.

The glass article thus produced can have an increased intensity (e.g., concentration) of hydrogen ions and a decreased intensity (e.g., concentration) of alkali ions at a depth of several tens of nanometers from the surface. In some embodiments, the ratio of the intensity (e.g., concentration) of hydrogen ions at the depth of 30 nm from the surface of the glass article and the intensity (e.g., concentration) of ion-exchanged hydrogen ions at the surface of the glass article may be 1:4 to 1.6. According to an embodiment of the present disclosure, the ratio of the intensity (e.g., concentration) of hydrogen ions at the depth of 30 nm from the surface of the glass article and the intensity (e.g., concentration) of ion-exchanged hydrogen ions at the surface of the glass article may be equal to or greater than 1:5.

In some embodiments, the ratio of the intensity (e.g., concentration) of alkali ions at the depth of 30 nm from the surface of the glass article and the intensity (e.g., concentration) of ion-exchanged alkali ions at the surface of the glass article may be equal to or greater than 1:0.1. According to an embodiment of the present disclosure, the ratio of the intensity (e.g., concentration) of alkali ions at the depth of 30 nm from the surface of the glass article and the intensity (e.g., concentration) of ion-exchanged alkali ions at the surface of the glass article may range from 1:0.05 to 1:0.1.

The ratios were obtained by measuring the numbers of hydrogen ions and alkali ions, e.g., intensities (e.g., concentrations) at a depth of several tens of nanometers from the surface of the glass article by D-SIMS (Dynamic secondary mass spectrometry). In the glass article according to embodiments of the present disclosure, the ratio of the intensity (e.g., concentration) of hydrogen ions at the surface relative to that at the depth of 30 nm of the glass article may be 1:4 to 1:6, and the ratio of the intensities (e.g., concentrations) of alkali ions may be 1:0.05 to 1:0.1. At the depth of 30 nm from the surface of the glass article, the ratios of intensities (e.g., concentrations) of ion-exchanged hydrogen and alkali ions at the surface of the glass article no longer increase and accordingly become saturated.

As shown in the experimental examples described below, by applying the above-described cleaning process, the intensity (e.g., concentration) of alkali ions may decrease as the intensity (e.g., concentration) of hydrogen ions increases at the surface of the glass article. Accordingly, the impact resistance of the surface of the glass article can be improved.

Hereinafter, the embodiments will be described in more detail with reference to Example and Experimental Examples.

### Preparation Example

A glass plate having a 100 μm thickness was prepared, and then first cleaning, stacking, cutting, chamfering, separating, second cleaning, first healing, third cleaning, strengthening, fourth cleaning, second healing and fifth cleaning were carried out, to produce a glass article.

### Comparative Example

The glass was immersed in deionized water (DI water) and potassium hydroxide (KOH) for 20 minutes at the temperature of 40° C., and the first to fifth cleaning was carried out, to produce a glass article.

### Example 1

A glass article was produced under the same conditions as in the Comparative Example, except that the glass was immersed in deionized water (DI water) for 20 minutes at the temperature of 80° C., and the first to fifth cleaning was carried out.

### Example 2

A glass article was produced under the same conditions as in the Comparative Example, except that the glass was immersed in deionized water (DI water) for 40 minutes at the temperature of 80° C., and the first to fifth cleaning was carried out.

### Example 3

A glass article was produced under the same conditions as in the Comparative Example, except that the glass was immersed in deionized water (DI water) for 40 minutes at the temperature of 100° C., and the first to fifth cleaning was carried out.

### Experimental Example: Pen Test

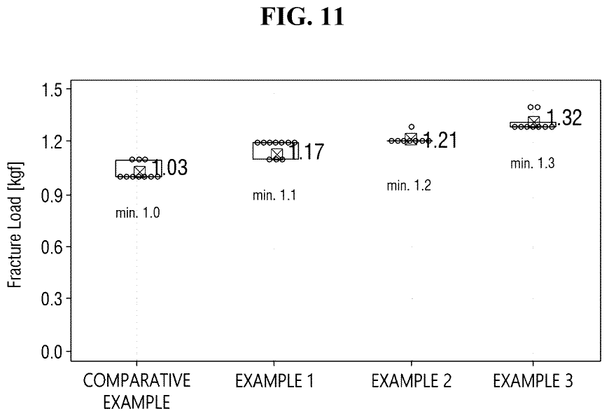

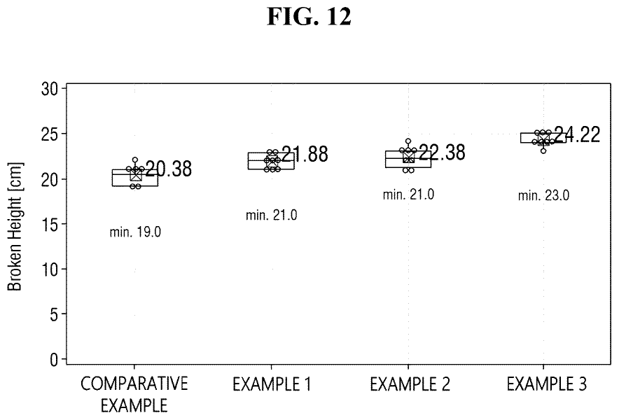

The glass articles according to the Comparative Example, Example 1, Example 2 and Example 3 were attached to an OLED panel as a cover window, and then a pen pressure test and a pen drop test were conducted. The results are shown in FIGS. 11 and 12.

FIG. 11 is a graph showing the results of a pen pressure test of glass according to the Experimental Example. FIG. 12 is a graph showing the results of a pen drop test of glass according to the Experimental Example.

Referring to FIG. 11, in the pen pressure test, the panel having the glass article attached thereto was fixed on a stone table, and a pen was fixed to a universal testing machine (UTM). The diameter of the pen was 0.3π and the weight was 5.35 g. The pen was dropped at the speed of 6 mm/min to press the glass article. The pen was dropped repeatedly, and the fracture load was checked when the glass was broken.

The fracture load of the glass article according to the Comparative Example was 1.03 kgf. On the other hand, the fracture load of the glass article according to Example 1 was 1.17 kgf, the fracture load of the glass article according to Example 2 was 1.21 kgf, and the fracture load of the glass article according to Example 3 was 1.32 kgf.

It can be seen from the results that the fracture load where the glass article is broken increases with the temperature range of the second to fifth cleaning processes and with the immersion time.

Referring to FIG. 12, in the pen drop test, the panel having the glass article attached thereto is fixed on the stone table. Then, the pen was fixed to the machine using an electromagnet, and then was dropped onto the glass article by operating the switch. The pen had a diameter of 0.3π and a weight of 5.35 g, and the drop height of the pen was moved by 0.1 cm in the range of 0.5 cm to 30 cm. The pen was repeatedly dropped until the glass is broken, and the height was checked.

The glass article according to the Comparative Example was broken when the pen was dropped at a height of 20.38 cm. On the other hand, the glass article according to Example 1 was broken when the pen was dropped at a height of 21.88 cm, the glass article according to Example 2 was broken when the pen was dropped at a height of 22.38 cm, and the glass article according to Example 3 was broken when the pen was dropped at the height of 24.22 cm.

It can be seen from the results that the drop height of the pen increases with the temperature range of the second to fifth cleaning processes and with the immersion time.

It can be seen from the Experimental Example that the glass articles produced according to the method of producing glass articles of the present disclosure had improved impact resistance.

### Experimental Example: Hydrogen and Alkali Ion Analysis

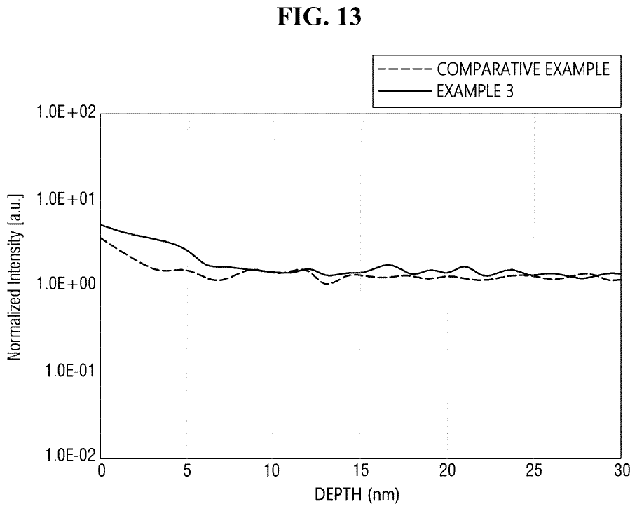

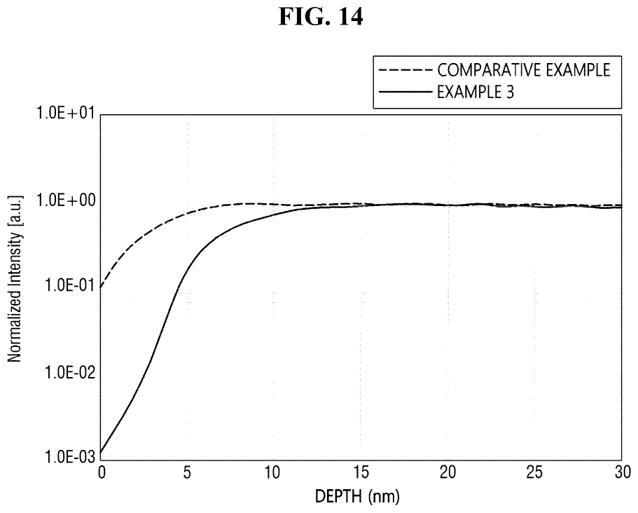

The intensity of hydrogen ions and the intensity of alkali ions in at the depth of 30 nm from the surface of the glass articles produced according to the above Comparative Example and Example 3 were measured using D-SIMS (Dynamic secondary mass spectrometry). The results are shown in Table 1 and FIGS. 13 and 14 below.

FIG. 13 is a graph showing the distribution of hydrogen ions in the glass article measured according to Experimental Example. FIG. 14 is a graph showing the distribution of alkali ions in the glass article measured according to Experimental Example.

TABLE 1

Ratio of Intensity at Glass Surface to Intensity
at 30 nm Depth of Glass Article (%)

| | Comparative Example | Example 3 |
|---|---|---|
| Hydrogen ions | 370.0 | 517.7 |
| Alkali ions | 9.8 | 0.1 |

Referring to FIGS. 13 and 14 in conjunction with Table 1 above, the glass article according to the Comparative Example showed the ratio of intensity of hydrogen ions at the glass surface to the intensity at the 30 nm depth of the glass article of 370%, and the ratio of intensities of alkali ions of 9.8%. On the contrary, the glass article according to Example 3 showed the ratio of intensity of hydrogen ions at the glass surface to the intensity at the 30 nm depth of the glass article of 517.7%, and the ratio of intensities of alkali ions of 0.1%

It can be seen from the results that the hydrogen ions were significantly increased while the alkali ions were significantly decreased at the glass surface of the glass article according to Example 3 compared to the Comparative Example.

In concluding the detailed description, those skilled in the art will appreciate that many variations and modifications can be made to the disclosed embodiments without substantially departing from the principles of the present disclosure. Therefore, the disclosed embodiments of the present disclosure are used in a generic and descriptive sense only and not for purposes of limitation.

What is claimed is:

1. A glass article, wherein a ratio of an intensity of hydrogen ions at a depth of 30 nm from a surface to an intensity of hydrogen ions at the surface is equal to or greater than 1:4.

2. The glass article of claim 1, wherein the ratio of the intensity of hydrogen ions at the depth of 30 nm from the surface to the intensity of hydrogen ions at the surface ranges from 1:4 to 1:6.

3. The glass article of claim 1, wherein a ratio of an intensity of alkali ions at a depth of 30 nm from the surface to an intensity of alkali ions at the surface ranges from 1:0.05 to 1:0.1.

4. The glass article of claim 1, wherein the glass article comprises LAS glass-ceramic.

5. The glass article of claim 4, wherein the glass article comprises SiO₂, Li₂O and Al₂O₃, and further comprises at least one selected from Na₂O, K₂O, MgO, P₂O₅, B₂O₃, CaO, SrO, BaO, ZnO, TiO₂ and ZrO₂.

6. The glass article of claim 1, wherein the glass article has a thickness in a range from 20 μm to 100 μm.

7. The glass article of claim 1, wherein the glass article is foldable.

8. A method of producing a glass article, the method comprising:
forming glass;
stacking the glass to create a stack of glasses;
cutting the stack of glasses to separate it into individual glasses;
first healing the glass;
first cleaning the glass;
strengthening the glass;
second cleaning the glass;
second healing the glass; and
third cleaning the glass,
wherein at least one selected from the first cleaning, the second cleaning and the third cleaning uses deionized water at a temperature in a range of 80° C. to 100° C.

9. The method of claim 8, wherein at least one selected from the first cleaning, the second cleaning and the third cleaning is performed by dipping and/or spraying.

10. The method of claim 8, wherein at least one selected from the first cleaning, the second cleaning and the third cleaning is performed for several minutes to tens of minutes.

11. The method of claim 8, wherein hydrogen ions and alkali ions are ion-exchanged at the surface of the glass in at least one selected from the first cleaning, the second cleaning and the third cleaning.

12. The method of claim 8, further comprising:
fourth cleaning the glass between the separating and the first healing,
wherein the fourth cleaning uses deionized water at a temperature in a range of 80° C. to 100° C.

13. The method of claim 8, further comprising:
chamfering the glass after the cutting the stack of glasses,
wherein the chamfering is carried out via a chemical polishing process.

14. A display device comprising:
a display panel comprising a plurality of pixels;
a cover window on the display panel; and
an optically clear coupling layer between the display panel and the cover window,
wherein a ratio of an intensity of hydrogen ions at a depth of 30 nm from a surface of the cover window to an intensity of hydrogen ions at the surface is equal to or greater than 1:4.

15. The display device of claim 14, wherein the ratio of the intensity of hydrogen ions at the depth of 30 nm from the surface to the intensity of hydrogen ions at the surface ranges from 1:4 to 1:6 in the cover window.

16. The display device of claim 14, wherein a ratio of an intensity of alkali ions at a depth of 30 nm from the surface to an intensity of alkali ions at the surface ranges from 1:0.05 to 1:0.1 in the cover window.

17. The display device of claim 14, wherein the cover window comprises LAS glass-ceramic.

18. The display device of claim 14, wherein the cover window comprises SiO₂, Li₂O and Al₂O₃, and further comprises at least one selected from Na₂O, K₂O, MgO, P₂O₅, B₂O₃, CaO, SrO, BaO, ZnO, TiO₂ and ZrO₂.

19. The display device of claim 14, wherein the cover window has a thickness in a range from 20 μm to 100 μm.

20. The display device of claim 14, wherein the cover window is foldable.
